(19) United States
(12) Patent Application Publication
(10) Pub. No.: US 2002/0043984 A1
(43) Pub. Date: Apr. 18, 2002

(54) Support carrier for temporarily attaching integrated circuit chips to a chip carrier and method

(75) Inventor: Otto Andreas Torreiter, Leinfelden-Echt (DE)

Correspondence Address: IBM MICROELECTRONICS, INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 09/682,717

(22) Filed: Oct. 10, 2001

(30) Foreign Application Priority Data
Oct. 13, 2000 (EP) 00122200.9

(51) Int. Cl. G01R 31/02

(52) U.S. Cl. 324/758

(57) ABSTRACT

An apparatus for temporarily attaching an integrated circuit chip to a chip carrier for subsequent electrical testing of the integrated circuit chip is provided consisting of a support carrier and a compression adjusting device to apply a compressive force via the support carrier to the integrated circuit chip to be tested, whereby the support carrier is arranged between the compression adjusting device and the integrated circuit chip to be tested, as well as a method for temporarily attaching an integrated circuit chip to a chip carrier. Furthermore, the support carrier is adapted to function as a transport vehicle for the integrated circuit chip.

### BACKGROUND OF THE INVENTION

1. Field of the Invention

The present invention relates to integrated circuit chip testing. More specifically, the invention relates to a temporary connection of the integrated circuit chip to be tested to a chip carrier.

2. Background of the Invention

As integrated circuits (ICs) have become more complicated, means for testing IC chips have similarly become more complicated and more expensive. These chips often have several hundred connector pins or even more which challenge the tester to provide complete and secure electrical contact with each pin, in a non-destructive way. Accordingly, cost effective chip development requires chip test fixtures that provide for non-destructive, easy installation and removal of the chip from the test device.

Today's state of the art principle to test high pin count chips with area footprint and C4 (flip chip) technology, after low pin count wafer test has been executed and the chip has been diced for further full pin count testing, is to temporarily but fixedly attach the chip onto a single chip carrier, the so called Temporary Chip Attach (TCA) carrier as shown in FIG. 1.

The problem with a TCA is the need for a complex, time consuming and hot process step (soldering) to get the chip mechanically as well as electrically fixed to the TCA and to get it sheared off the TCA after testing has been finished. In case there is a need to retest the chip these additional process steps have to be repeated.

Another problem is that in case the chip has to be removed from the final product, e.g., a Multi Chip Module (MCM) to diagnose for failure symptoms, the chip has once more to be attached/soldered to the TCA. This additional hot process step sometimes results in a NDF (No Defect Found) situation because of unpredictable, self healing effects on the chip under investigation because of the additional hot solder process step.

U.S. Pat. No. 5,532,612 discloses methods and an apparatus for test and burn-in of integrated circuit devices using specially adapted reusable test carriers. After depositing a limited amount of solder the ICs are mounted to the test carriers and the solder is reflowed to fix the ICs on the carrier.

In U.S. Pat. No. 5,528,462 there is disclosed an easily reworkable demountable means of electrically interconnecting an integrated circuit die to a substrate. Compression means for maintaining the integrated circuit die contacts in electrical communication with the contacts of the substrate are provided. The compression means typically includes a two-part spring system which provides superior electrical contact by causing the curvature of the integrated circuit die to be in the same direction as the curvature of the substrate.

U.S. Pat. No. 5,006,792 describes a flip-chip test socket adaptor consisting of a substrate, multiple cantilever beams and a package. A bare chip may be inserted into and held by the test socket adapter for insertion into a standard test socket.

IBM Technical Disclosure Bulletin, Vol. 36, No. 7, July 1993, pp. 137-138 discloses an interposer for Direct Chip Attach (DCA) or Surface Mount Array (SMA) devices providing a means of temporarily attaching direct chip attach or surface mount array electronic components. The basic structure of the interposer, which is attached permanently to a circuit carrier is a traditional ceramic package modified such that C4 or SMA solder balls are applied to the side which will contact the circuit carrier. The top surface of the ceramic package is plated with palladium dendrites. Thus, components can be placed on the dendritic contacts, tested and removed without significant damage to C4 or SMA solder balls. Additionally, a means of restraining the device on the dendritic surface, such as a spring clip, may be secured to the alignment aid.

Finally, in U.S. Pat. No. 5,770,891 there is described a socket for temporarily attaching a flip chip die or ball grid array (BGA) devices to a printed circuit board substrate. Compression adjusting means are provided to compress the BGA and the board by means of a rigid cap or block arranged between the compression means and the BGA to cause dendritic penetration into BGA device balls and board contacts.

The devices and methods described in the state of the art as presented heretofore have the disadvantages that they either need additional soldering steps to get the chip electrically and mechanically connected to the test sockets, or they show a complicated design and the chip cannot be removed easily. Another disadvantage resides in the fact that they do not provide a reliable and easy method of adjusting the chip to the TCA or the chip carrier.

### BRIEF SUMMARY OF THE INVENTION

### SUMMARY OF THE INVENTION

It is therefore an object of the present invention to provide an improved support carrier for use in a device for temporarily attaching an integrated circuit chip to a chip carrier for subsequent electrical testing of the integrated circuit chip.

It is another object of the present invention to provide a device for temporarily attaching an integrated circuit chip to a chip carrier for subsequent electrically testing the chip without the need of an additional soldering step.

It is still another object of the present invention to provide such a device that can be easily moved to a test system for further testing.

Furthermore, it is an object of the present invention to provide a method for temporarily attaching an integrated circuit chip to a chip carrier for subsequent electrical testing of the integrated circuit chip that allows easy attaching and detaching of the integrated circuit chip, independent of chip size or type as long as the C4 ball pattern of different chip sizes or types fit to the pad area of the TCA.

### BRIEF DESCRIPTION OF THE SEVERAL VIEWS OF THE DRAWINGS

### BRIEF DESCRIPTION OF THE DRAWINGS

The present invention will in the following be described in more detail in connection with the accompanying drawings, in which:

FIG. 1 shows a single chip carrier used to temporarily attach an integrated circuit chip according to the state of the art;

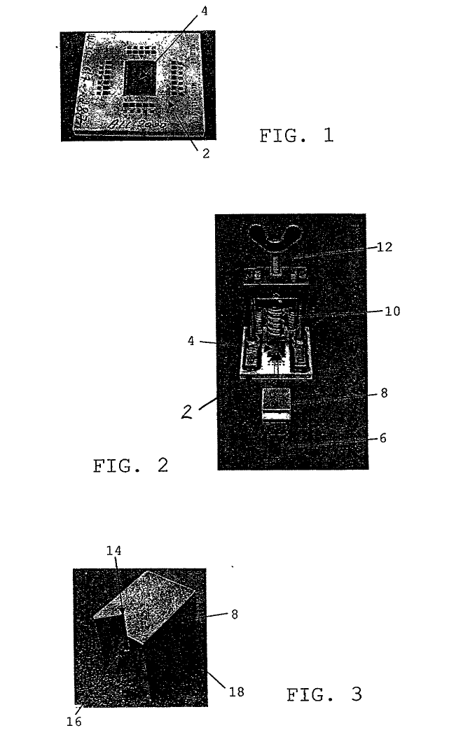

FIG. 2 depicts a device for temporarily attaching an integrated circuit chip to a single chip carrier (STCA) for subsequent electrical testing according to the present invention;

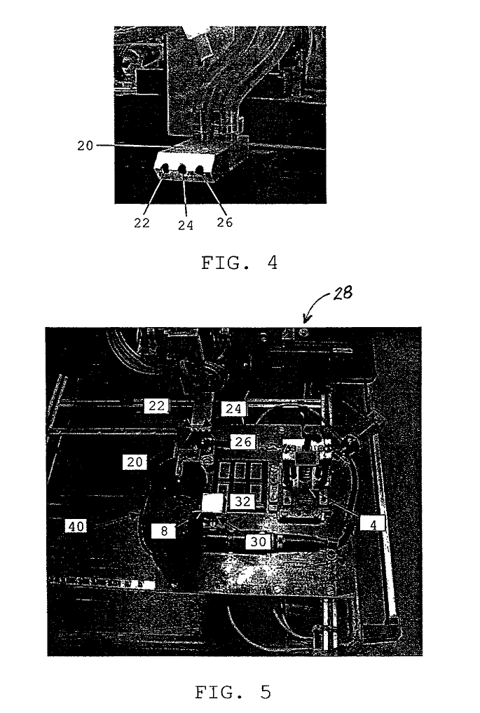

FIG. 3 shows a support carrier according to the present invention;

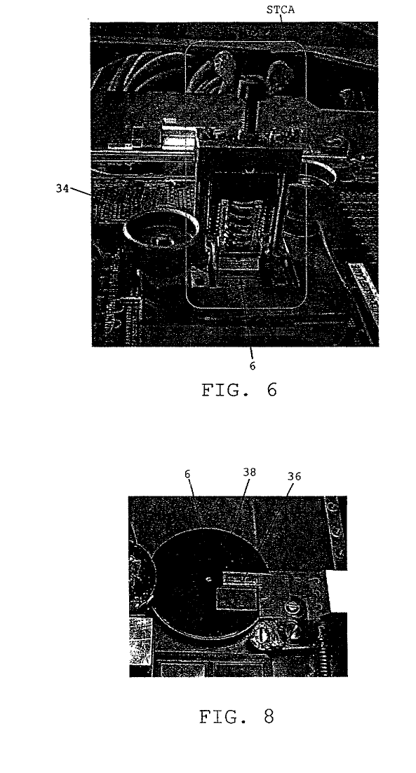

FIG. 4 depicts a handler arm used in the method according to the present invention;

FIG. 5 is a picture showing a device for temporarily attaching an integrated circuit chip to a single chip carrier according to the present invention in conjunction with an alignment system;

FIG. 6 depicts the device of to FIG. 2 being inserted into a test system connector;

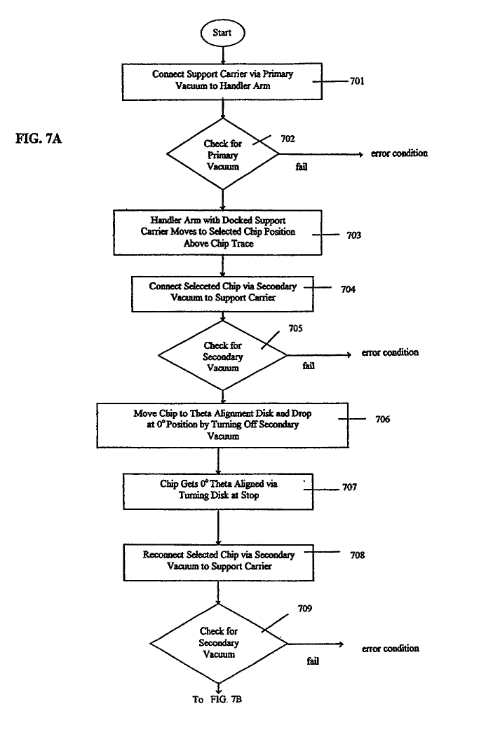

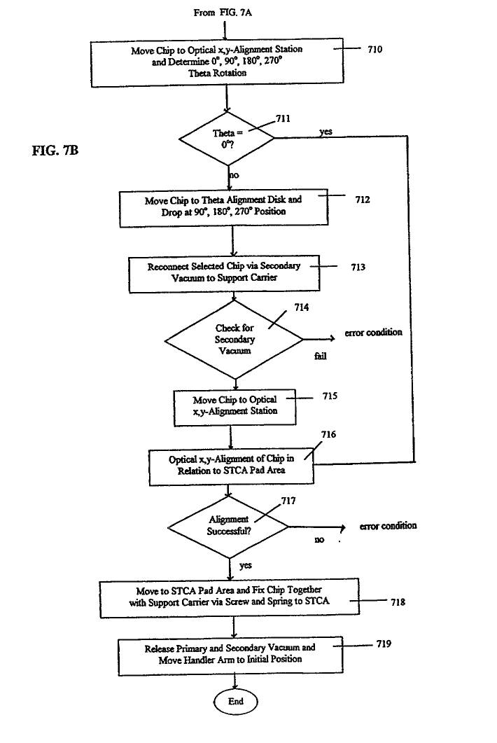

FIG. 7 is a flowchart showing the chip alignment process according to the present invention; and

FIG. 8 shows part of the alignment system to align the chip to be tested.

### DETAILED DESCRIPTION OF THE INVENTION

### DETAILED DESCRIPTION OF THE PREFERRED EMBODIMENT

FIG. 1 shows single chip carrier 2 having pad area 4 used to receive a single chip (not shown) in order to subsequently perform full pin count testing on a test system. The chip to be tested is temporarily attached to the carrier's chip area, usually by a hot process step (soldering step) to get the chip mechanically as well as electrically attached. This soldering step is a complex, time-consuming process and, in addition, the tested chip has to be sheared off the carrier again after testing has been finished. Furthermore, in case of a need to retest the chip these additional process steps will have to be performed several times.

Another problem arises in case a chip has been removed from the final product, e.g., a Multi Chip Module (MCM), to diagnose the chip for fail symptoms. Then, the chip has to be once again attached/soldered to the single chip carrier. This additional hot process sometimes results in a NDF (No Defect Found) situation because of unpredictable, self healing effects on the chip under investigation due to the additional hot solder process step.

The solution to these problems is the STCA (Solderless Temporary Chip Attach with Support Carrier) approach, which will be discussed in greater detail now. One important feature of this approach is the fact that the need of solder attaching the chip by an additional hot process to the carrier and the mechanical removal process (chip shearing) after testing can be eliminated.

FIG. 2 shows the STCA device in a depopulated state, i.e., without the chip and the support carrier being mounted. In order to bring the STCA device in an operable condition, chip 6 to be tested is first fixed to support carrier 8. This can be done by applying a vacuum. Next, support carrier 8 with chip 6 fixed to it is placed on pad area 4 of single chip carrier 2. It has to be noted that this placement has to be done such that the chip is exactly aligned with the pad area of the single chip carrier in order to ensure that the electrically connecting elements, namely the pattern of C4 balls, fits with the respective pattern of the pad area on the single chip carrier to guarantee exact testing. This alignment can be achieved by an appropriate alignment system which will be described later. It has to be noted that the pad area of the carrier may be observed by a secondary camera (not shown) in order to achieve a proper probe-to-pad alignment in case there are carriers of different size or differing dimensions.

Next, support carrier 8 and chip 6 will be mechanically as well as electrically connected to pad area 4 of single chip carrier 2. In FIG. 2, spring 10 and screw 12 are shown as a compression adjusting means. By twisting screw 12 in the right direction (clockwise in FIG. 2), spring 10 will apply a compression force on support carrier 8 and chip 6 attached thereto to thereby connect chip 6, mechanically as well as electrically, to pad area 4 without having to apply any solder.

It will be noted that applying a compression force can of course be realized using other arrangements than screw 12 and spring 10. For example, a pneumatic or hydraulic structure can be used, operating pistons which then press together the chip and the single carrier pad area. The advantage of spring 10 or another equally acting structure is that the mechanical pressure onto chip 6 and, as a result, the electrical contact stay constant even though the C4 balls do mechanically (non-destructively) deform. The spring pressure has to be applied substantially concentric in relation to chip 6 and pad area 4 of single chip carrier 2.

A further advantage of the device according to the invention is the fact that the only further requirement is a mechanical fixture for the spring and the screw attached to the standard TCA.

In FIG. 3 there is shown support carrier 8 according to the present invention. The support carrier carries on its one side triangle notch 14 which is to cooperate with a handler arm described later. On the side carrying notch 14 and on a side rectangular to this side carrier 8 has two holes 16, 18 defining in—and outlet for applying a secondary vacuum through support carrier 8 which may serve to pick up chip 6 at a chip trace (32 in FIG. 5), where it will stay until testing has been completed.

Another significant advantage of support carrier 8 according to the invention, whose primary usage is to act as a transport vehicle for chip 6, is its flexibility to implement further functions not shown in the realization in FIG. 3. Such functions could include heating and cooling the chip, or the measurement of the temperature of the chip under test.

Referring now to FIG. 4, handler arm 20 according to the present invention is shown. Handler arm 20 has at its front end a wedge-shaped form which exactly matches with triangle notch 14 of support carrier 8. Handler arm 20 is, at its front, wedge-shaped end provided with through holes 22, 24, 26 in order to provide first and second vacuums to pick up chip 6 to be tested and to dock to support carrier 8. A first vacuum is applied via through holes 22, 26 to dock handler arm 20 to support carrier 8. A second vacuum is applied via through hole 24 to pick up chip 6 to be tested.

FIG. 5 shows the STCA in conjunction with alignment system 28 to properly align chip 6 to be tested on pad area 4 of single chip carrier 2. Handler arm 20 docks to support carrier 8 sitting at carrier rest 30 by applying a first vacuum via left and right most through holes 22, 26 at handler arm 20. Then handler arm 20 together with the vacuum docked support carrier 8 moves to a selectable chip position in chip trace 32 and picks up chip 6 to be tested by means of a second vacuum provided via the middle handler arm through hole 24 and support carrier hole 16. Chip 6, together with support carrier 8 will then be exactly aligned in relation to STCA pad area 4 and simply be fixed with screw 12 and spring 10 to pad area 4. Handler arm 20 is subsequently detached from support carrier 8 by switching off the first and second vacuums, and drawn back. Thus, support carrier 8 carrying chip 6 is first attached to handler arm 20, and, after detaching handler arm 20, remains in contact with the TCA.

The whole STCA carrying chip 6 under test can now be simply put into test system connector 34 as shown in FIG. 6, and, accordingly, chip 6 is electrically connected to the test system, Burnin (BI) oven or the like for further testing.

The present invention is not restricted to attaching a chip to a single chip carrier but can also be used with multiple chip carriers such as an MCM. However, the invention has been described above in connection with a single chip carrier for the sake of simplicity.

As has already been mentioned above, chip 6, after having been picked up by support carrier 8, will have to be aligned with respective pad area 4 of the respective chip carrier in order to ensure that the connecting elements, namely the pattern of C4 balls, fits with the respective pattern of pad area 4 of the chip carrier to guarantee exact testing.

FIG. 7 shows a flowchart depicting the steps necessary to align the chip to be tested correctly. When starting the process, support carrier 8 is connected via primary vacuum to handler arm 20 (Box 701). Next, the conditions for the primary vacuum are checked in Box 702. In case the vacuum is not applied correctly, an error message is outputted. If the vacuum has been applied correctly, the process proceeds to Box 703 where handler arm 20 with docked support carrier 8 moves to a selected chip position above chip trace 32. Next, in Box 704, selected chip 6 is connected via the secondary vacuum to support carrier 8. Again, it is checked whether the vacuum has been applied correctly (Box 705) and an error message is outputted if this is not the case. In Box 706, where the process procceeds to if the vacuum has been applied correctly, chip 6 is moved to theta alignment disk 38 (shown in FIG. 8) and dropped at the 0 degree position by turning off the secondary vacuum. Here, in Box 707, chip 6 gets 0 degree theta-aligned at stop 36 (FIG. 8) via turning the disk. After the thetaalignment has been successful, the process proceeds to Box 708 where selected chip 6 is reconnected via the secondary vacuum to support carrier 8. In Box 709 a vacuum check takes place again like in Boxes 702 and 705. In case the vacuum is found ok, chip 6 is moved to optical x,y-alignment station 40 in Box 710 where 0, 90, 180 and 270 degree theta rotation is determined. In Box 711 it is determined whether theta is 0 degrees. In case it is not, the process proceeds to Box 712 where chip 6 is moved to theta-alignment disk 38, dropped at 90, 180 or 270 degree position and gets finally 0o aligned at stop 36 because of the turning disk. Subsequently, chip 6 is reconnected to support carrier 8 via the secondary vacuum in Box 713 and, after checking the vacuum conditions again in Box 714, again moved to optical x,y-alignment station 40 in Box 715. In case it is determined that theta is 0 degrees in Box 711, the process immediately proceeds to Box 716, where optical x,y-alignment of chip 6 in relation to STCA pad area 4 takes place. In case the alignment is successful, chip 6 is moved to STCA pad area 4 and fixed together with support carrier 8 via screw 12 and spring 10 to the STCA in Box 717, whereas, in case the alignment was unsuccessful, a respective error message is outputted (Box 718). Finally, the primary and secondary vacuums are released and handler arm 20 is moved to its initial position (Box 719).

The advantages of the present invention include shorter turn-around-time (TAT) because of the eliminated solder/removal process time so the chip gets quickly connected to the test system, BI equipment and the like. Also, much higher TCA reuse cycles are achieved because of the thermally neutral process (only the pad area needs to be cleaned from time to time). This and the shorter TAT also results in the need for less TCA hardware in the manufacturing environment. Chips that are not sitting on carriers can be quickly remounted and retested without soldering, which is especially important in the case of characterization activities where chips need to be retested several times. An NDF situation can be avoided in the case of diagnostic activities on line/field chip returns because of the eliminated solder process. Other advantages include the support carrier can be equipped with additional functions/features like chip temperature application and measurement, a simple state of the art TCA carrier can be used as a basis fitting already into the given tester frontend, and chip size and type may vary as long as the pad area size (TCA) is a superset of the chip C4 ball pattern.

Although specific embodiments of the present invention have been illustrated in the accompanying drawings and described in the foregoing detailed description, it will be understood that the invention is not limited to the particular embodiments described herein, but is capable of numerous rearrangements, modifications and substitutions without departing from the scope of the invention. The following claims are intended to encompass all such modifications.

What is claimed is:

1] Apparatus for holding an integrated circuit chip during electrical testing, the apparatus comprising:
a chip carrier,
a support carrier for temporarily attaching to the integrated circuit chip, and
compression adjusting device which applies a compressing force via the support carrier to the integrated circuit chip for temporarily attaching the integrated circuit chip to the chip carrier.

2] Apparatus according to claim 1, wherein the compression adjusting device comprises a spring and a screw.

3] Apparatus according to claim 1, wherein the compressing force is applied by a piston.

4] Apparatus according to claim 1, wherein the support carrier is adapted to function as a transport vehicle for the integrated circuit chip.

5] Apparatus according to claim 1, wherein the chip carrier is a single chip carrier.

6] Apparatus according to claim 1, wherein the chip carrier is a multiple chip carrier.

7] Apparatus according to claim 1, wherein the support carrier is further adapted to provide additional functions to the integrated circuit chip.

8] Apparatus according to claim 7, wherein the additional functions comprise heating or cooling of the integrated circuit chip.

9] Apparatus according to claim 7, wherein the additional functions comprise measuring the temperature of the integrated circuit chip.

10] Apparatus according to claim 1, wherein the support carrier comprises a triangle notch on one of its sides adapted to cooperate with a handler arm.

11] Apparatus according to claim 1, wherein the support carrier comprises holes for applying a vacuum to the integrated circuit chip to be picked up by the support carrier.

12] Method for electrical testing of an integrated circuit chip comprising the steps of:
a) temporarily attaching the integrated circuit chip to a support carrier;
b) placing the integrated circuit chip temporarily attached to the support carrier on a pad area provided on a chip carrier; and
c) making temporary electrical and mechanical connection of the integrated circuit chip temporarily attached to the support carrier to the pad area.

13] Method according to claim 12, wherein in the temporarily attaching step (a) the integrated circuit chip is temporarily attached to the support carrier by applying a first vacuum.

14] Method according to claim 12, wherein the making temporary electrical and mechanical connection step (c) is carried out without applying any solder.

15] Method according to claim 12, wherein the making temporary electrical and mechanical connection step (c) is carried out by a compression adjusting means.

16] Method according to claim 15, wherein a compression force generated by the compression adjusting means is applied substantially concentric to the pad area.

17] Method according to claim 12, wherein prior to the temporarily attaching the integrated circuit chip to the support carrier step (a), performing the steps of:
docking the support carrier to a handler arm; and
moving the handler arm to a selectable chip position.

18] Method according to claim 17, wherein the docking step is carried out by applying a second vacuum via the handler arm.

19] Method according to claim 18, wherein the first and the second vacuums are applied via holes present in the handler arm.

20] Method according to claim 17, further comprising the step of aligning the integrated circuit chip temporarily attached to the support carrier in relation to the pad area on the chip carrier.

21] Method according to claim 20, wherein the step of aligning the integrated circuit chip is carried out by means of a theta-alignment disk and an optical x,y-alignment station.
